(19) United States
(12) Patent Application Publication
(10) Pub. No.: US 2022/0347814 A1
(43) Pub. Date: Nov. 3, 2022

(54) POLISHING APPARATUS AND POLISHING METHOD

(71) Applicant: EBARA CORPORATION, Tokyo (JP)

(72) Inventors: BAN ITO, Tokyo (JP); YASUYUKI MOTOSHIMA, Tokyo (JP); SEUNGHO YUN, Tokyo (JP); SHUJI UOZUMI, Tokyo (JP); SHUMPEI MIURA, Tokyo (JP); HISANORI MATSUO, Tokyo (JP); KENICHI SUZUKI, Tokyo (JP)

(73) Assignee: EBARA CORPORATION, Tokyo (JP)

(21) Appl. No.: 17/730,202

(22) Filed: Apr. 27, 2022

(30) Foreign Application Priority Data
Apr. 28, 2021 (JP) 2021-076092
Sep. 30, 2021 (JP) 2021-162212

(51) Int. Cl. B24B 37/04

(52) U.S. Cl. CPC B24B 37/042

(57) ABSTRACT

A polishing apparatus includes a polishing table which supports a polishing pad, a polishing head which polishes a substrate by pressing the substrate against a polishing surface of the polishing pad, a pad temperature measuring device which measures a temperature of the polishing surface, a pad temperature adjusting device which adjusts the temperature of the polishing surface, and a control device which controls the operation of the pad temperature adjusting device based on the temperature of the polishing surface measured by the pad temperature measuring device. The pad temperature adjusting device includes a pad heater which is disposed to be separated upward from the polishing surface, and the pad heater includes a longitudinal portion which extends in a substantially radial direction of the polishing pad and a slit-shaped injection port which is formed in a longitudinal direction of the longitudinal portion and injects a heating fluid toward the polishing surface.

### CROSS-REFERENCE TO RELATED APPLICATION

This application claims the priority benefits of Japanese application no. 2021-076092, filed on Apr. 28, 2021, and Japanese application no. 2021-162212, filed on Sep. 30, 2021. The entirety of each of the above-mentioned patent applications is hereby incorporated by reference herein and made a part of this specification.

### BACKGROUND

### Technical Field

The disclosure relates to a polishing apparatus and a polishing method of polishing a substrate such as a semiconductor wafer by sliding the substrate in contact with a polishing pad and particularly to a polishing apparatus and a polishing method of polishing a substrate while adjusting a surface temperature of a polishing pad.

### Description of Related Art

A chemical mechanical polishing (CMP) device is used in a process of polishing a surface of a substrate in the manufacture of semiconductor devices. The CMP device holds the substrate by a polishing head, rotates the substrate, and presses the substrate against a polishing pad on a rotating polishing table to polish the surface of the substrate. During polishing, a polishing liquid (slurry) is supplied to the polishing pad and the surface of the substrate is flattened by the chemical action of the polishing liquid and the mechanical action of abrasive grains contained in the polishing liquid.

The polishing rate of the substrate depends not only on the polishing load on the polishing pad of the substrate but also on the surface temperature of the polishing pad. This is because the chemical action of the polishing liquid on the substrate depends on the temperature. Thus, in the manufacture of semiconductor devices, in order to increase the polishing rate of the substrate and maintain the polishing rate constant, it is important to maintain the surface temperature of the polishing pad during substrate polishing at an optimal value.

Here, a pad temperature adjusting device for adjusting the surface temperature of the polishing pad has been conventionally used (for example, see Patent Documents 1 and 2 (Japanese Patent Laid-Open No. 2012-176449 and 2017-148933)). The pad temperature adjusting device includes a pad contact member (or a heat exchanger) that is in contact with the surface of the polishing pad and receives a heating liquid and a cooling liquid subjected to temperature adjustment. By adjusting the flow rate of the heating liquid and the flow rate of the cooling liquid supplied to the pad contact member, the surface temperature of the polishing pad during polishing of the substrate can be maintained at a desired temperature.

However, since the pad contact member of the pad temperature adjusting device is essentially in contact with the polishing liquid during polishing of the substrate, dirt such as abrasive grains contained in the polishing liquid and abrasion powder of the polishing pad adheres to the pad contact member. If dirt falls off from the pad contact member during polishing of the substrate, it may contaminate the substrate or cause defects such as scratches on the substrate. Further, since the dirt that has fallen off from the pad contact member may deteriorate the surface state of the polishing pad, there is a probability that the polishing performance may be adversely affected.

Here, the disclosure provides a polishing apparatus and a polishing method capable of polishing a substrate with a desired polishing performance without causing defects such as scratches and contamination on the substrate.

### SUMMARY

In an aspect, there is provided a polishing apparatus including: a polishing table which supports a polishing pad; a polishing head which polishes a substrate by pressing the substrate against a polishing surface of the polishing pad; a pad temperature measuring device which measures a temperature of the polishing surface; a pad temperature adjusting device which adjusts the temperature of the polishing surface; and a control device which controls an operation of the pad temperature adjusting device based on the temperature of the polishing surface measured by the pad temperature measuring device, wherein the pad temperature adjusting device includes a pad heater which is disposed to be separated upward from the polishing surface, and wherein the pad heater includes a longitudinal portion which extends in a substantially radial direction of the polishing pad and an injection port which is slit-shaped and formed in a longitudinal direction of the longitudinal portion and injects a heating fluid toward the polishing surface.

In an aspect, the pad temperature adjusting device further includes a vertical movement mechanism which moves the pad heater upward and downward with respect to the polishing surface.
In an aspect, the pad temperature adjusting device further includes a rotating mechanism which rotates the pad heater in a horizontal direction with respect to the polishing surface.
In an aspect, the pad temperature adjusting device further includes a rotation mechanism which rotates the pad heater about a longitudinal axis of the pad heater.

In an aspect, the pad temperature adjusting device further includes a shutter mechanism which adjusts an opening degree of the injection port.
In an aspect, the pad temperature measuring device is a measuring device capable of measuring a temperature profile in a radial direction of the polishing pad, and the shutter mechanism includes piezo elements arranged in a longitudinal direction of the injection port of the pad heater.
In an aspect, the control device adjusts an expansion and contraction amount of each piezo element based on the temperature profile.

In an aspect, the pad temperature adjusting device further includes a cooling mechanism which injects a cooling fluid to the polishing surface and cools the polishing surface.
In an aspect, the cooling mechanism includes a pad cooler which is disposed to be separated upward from the polishing surface, and the pad temperature adjusting device further includes a rotation mechanism which rotates the pad cooler about a longitudinal axis of the pad cooler.
In an aspect, the cooling mechanism includes the pad cooler which is disposed to be separated upward from the polishing surface, the pad cooler includes a longitudinal portion which extends in a substantially radial direction of the polishing pad and a plurality of injection ports which is arranged in a longitudinal direction of the longitudinal portion and injects the cooling fluid toward the polishing surface, and the cooling mechanism further includes a shutter mechanism which adjusts an opening degree of a plurality of injection ports of the pad cooler.
In an aspect, the cooling mechanism includes the pad cooler which is disposed to be
separated upward from the polishing surface, and the cooling mechanism further includes a
guide plate which is attached to the pad cooler and an actuator which rotates the guide plate.
In an aspect, the pad temperature adjusting device further includes a suction
mechanism which is disposed above the polishing surface and sucks air above the polishing surface.

In an aspect, the pad temperature adjusting device further includes a heater which is disposed in the pad heater.
In an aspect, the polishing table is disposed in a polishing chamber, and the pad temperature adjusting device further includes a polishing chamber suction device which sucks air in the polishing chamber so that a pressure in the polishing chamber is maintained at a predetermined value.
In an aspect, the polishing apparatus further includes a cleaning device which cleans the pad heater at a retreat position on a side of the polishing pad.
In an aspect, the heating fluid is superheated steam.

In an aspect, the control device executes a pad temperature adjustment start operation when starting surface temperature control of the polishing pad, and the pad temperature adjustment start operation is an operation of supplying the heating fluid having a flow rate and/or a temperature larger than a flow rate and/or a temperature of the heating fluid calculated so that the temperature of the polishing surface reaches a target temperature to the pad heater.
In an aspect, the pad temperature adjusting device further includes a heating fluid supply line which supplies the heating fluid to the pad heater and a flow rate regulator which is disposed in the heating fluid supply line, and the control device increases a flow rate of the heating fluid using the flow rate regulator during the pad temperature adjustment start operation.
In an aspect, the control device ends the pad temperature adjustment start operation when the temperature of the polishing surface of the polishing pad reaches the target temperature.

In an aspect, there is provided a polishing method of polishing a substrate by pressing the substrate against a polishing surface of a polishing pad while adjusting a temperature of the polishing surface using a pad heater disposed to be separated upward from the polishing surface, wherein when starting temperature control of the polishing surface, a pad temperature adjustment start operation is executed so that the temperature of the polishing surface reaches a target temperature, wherein the temperature of the polishing surface is maintained at the target temperature by injecting a heating fluid from an injection port which is slit-shaped and formed in a longitudinal portion of the pad heater based on the temperature of the polishing surface measured by a pad temperature measuring device measuring the temperature of the polishing surface during polishing of the substrate, and wherein the pad temperature adjustment start operation is an operation of supplying the heating fluid having a flow rate and/or a temperature larger than a flow rate and/or a temperature of the heating fluid calculated so that the temperature of the polishing surface reaches the target temperature to the pad heater.

In an aspect, a step of maintaining the temperature of the polishing surface at the target temperature is executed by at least one of an operation of adjusting the temperature and/or the flow rate of the heating fluid, an operation of adjusting a vertical movement of the pad heater with respect to the polishing surface, an operation of adjusting a rotation operation in a horizontal direction of the pad heater with respect to the polishing surface, and an operation of adjusting a rotation operation of rotating the pad heater about a longitudinal axis of the pad heater.
In an aspect, the flow rate of the heating fluid is adjusted by a shutter capable of adjusting an opening degree of the injection port of the pad heater.
In an aspect, the pad temperature measuring device is a measuring device capable of measuring a temperature profile in a radial direction of the polishing pad, the shutter includes piezo elements arranged in a longitudinal direction of the injection port of the pad heater, and the flow rate of the heating fluid is adjusted by adjusting an expansion and contraction amount of each piezo element based on the temperature profile.

In an aspect, a step of maintaining the temperature of the polishing surface at the target temperature is executed by the pad heater and a cooling mechanism for cooling the polishing surface by injecting a cooling fluid to the polishing surface.
In an aspect, the cooling mechanism includes a pad cooler which is disposed to be separated upward from the polishing surface, the pad cooler includes a longitudinal portion which extends in a substantially radial direction of the polishing pad and a plurality of injection ports which is arranged in a longitudinal direction of the longitudinal portion and injects the cooling fluid toward the polishing surface, and a step of maintaining the temperature of the polishing surface at the target temperature is executed by further adding at least one of an operation of adjusting a rotation operation of rotating the pad cooler about a longitudinal axis of the pad cooler, an operation of adjusting an opening degree of the plurality of injection ports of the pad cooler by a shutter, and an operation of adjusting a rotation operation of a guide plate attached to the pad cooler.
In an aspect, the pad temperature adjustment start operation is an operation of increasing the flow rate of the heating fluid using a flow rate regulator disposed in a heating fluid supply line supplying the heating fluid to the pad heater.
In an aspect, when the temperature of the polishing surface of the polishing pad reaches the target temperature, the pad temperature adjustment start operation is ended.

According to the disclosure, since the pad temperature adjusting device adjusts the temperature of the polishing surface of the polishing pad to a predetermined target temperature in a non-contact manner with the polishing surface of the polishing pad, the pad temperature adjusting device has no components to which dirt such as abrasive grains contained in the polishing liquid and abrasion powder of the polishing pad adheres. As a result, it is possible to prevent defects such as scratches and contamination caused by the dirt fallen off from the pad temperature adjusting device from occurring on the substrate. Further, since the surface state of the polishing pad does not change due to the dirt fallen off from the pad temperature adjusting device, it is possible to polish the substrate at a desired polishing rate exhibited when the temperature of the polishing surface of the polishing pad is maintained at a predetermined target temperature.

### BRIEF DESCRIPTION OF THE DRAWINGS

FIG. 1 is a schematic view showing a polishing apparatus according to an embodiment.

FIG. 2 is a schematic view showing a heating fluid supply system and a cooling fluid supply system according to an embodiment.

(a) of FIG. 3 is a schematic view showing a pad heater according to an embodiment, (b) of FIG. 3 is a cross-sectional view of the pad heater shown in (a) of FIG. 3, and (c) of FIG. 3 is a plan view showing an example of the arrangement of the pad heater with respect to a polishing pad 3.

(a) of FIG. 4 is a schematic view of a pad cooler according to an embodiment and (b) of FIG. 4 is a cross-sectional view of the pad cooler shown in (a) of FIG. 4.

(a) of FIG. 5 is a schematic view of a suction nozzle according to an embodiment and (b) of FIG. 5 is a cross-sectional view of the suction nozzle shown in (a) of FIG. 5.

(a) of FIG. 6 is a view showing an example in which a longitudinal portion of the pad heater and a longitudinal portion of the pad cooler are integrally formed with each other and (b) of FIG. 6 is a schematic view showing an example in which a common longitudinal portion functioning as both the longitudinal portion of the pad heater and the longitudinal portion of the pad cooler is provided.

FIG. 7 is a schematic view showing an example of a vertical movement mechanism.

(a) of FIG. 8 is a schematic view showing an example of a rotating mechanism and (b) of FIG. 8 is a plan view showing the pad heater rotated by the rotating mechanism.

(a) of FIG. 9 is a schematic view showing an example of a rotation mechanism rotating the pad heater about its longitudinal axis, (b) of FIG. 9 is a cross-sectional view a state when the pad heater shown in (a) of FIG. 9 is rotated upward, and (c) of FIG. 9 is a cross-sectional view showing a state when the pad heater shown in (a) of FIG. 9 is rotated downward.

FIG. 10 is a cross-sectional view schematically showing a pad heater according to another embodiment.

(a) of FIG. 11 is a perspective view of a shutter mechanism according to another embodiment as viewed from a lower surface side and (b) of FIG. 11 is a schematic view showing an example of an operation of the shutter mechanism shown in (a) of FIG. 11.

FIG. 12 is a graph showing an example of a target temperature profile of a polishing pad and a temperature profile acquired by a pad temperature measuring device.

FIG. 13 is a cross-sectional view schematically showing a pad heater according to still another embodiment.

FIG. 14 is a schematic view showing a polishing apparatus including a pad temperature adjusting device according to still another embodiment.

(a) of FIG. 15 is a schematic view showing a pad cooler of a cooling mechanism according to another embodiment and (b) of FIG. 15 is a cross-sectional view of the pad cooler shown in (a) of FIG. 15.

FIG. 16 is a cross-sectional view schematically showing a pad cooler of a cooling mechanism according to still another embodiment.

FIG. 17 is a schematic view showing the pad cooler of the cooling mechanism according to still another embodiment.

FIG. 18 is a graph illustrating an example of a pad temperature adjustment start operation.

FIG. 19 is a schematic view showing a polishing apparatus including a pad temperature adjusting device according to still another embodiment.

FIG. 20 is a schematic view showing a heating fluid supply system and a cooling fluid supply system according to another embodiment.

FIG. 21 is a schematic view showing a heating fluid supply system according to still another embodiment.

FIG. 22 is a schematic view showing a combination of a cooling fluid supply system and a suction mechanism according to another embodiment.

FIG. 23 is a schematic view showing a combination of a heating fluid supply system, a cooling fluid supply system, and a suction mechanism according to another embodiment.

### DESCRIPTION OF THE EMBODIMENTS

Hereinafter, embodiments of the disclosure will be described with reference to the drawings.

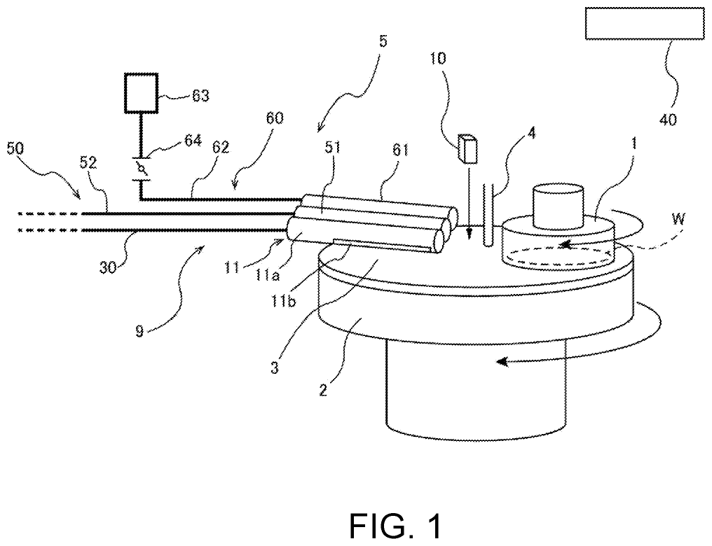

FIG. 1 is a schematic view showing a polishing apparatus according to an embodiment. The polishing apparatus shown in FIG. 1 includes a polishing head 1 which holds and rotates a wafer W as an example of a substrate, a polishing table 2 which supports a polishing pad 3, a polishing liquid supply nozzle 4 which supplies a polishing liquid (for example, slurry) to a surface of the polishing pad 3, a pad temperature measuring device 10 which measures a temperature of the surface of the polishing pad 3, and a pad temperature adjusting device 5 which adjusts a surface temperature of the polishing pad 3. The surface (upper surface) of the polishing pad 3 constitutes a polishing surface for polishing the wafer W.

Further, the polishing apparatus includes a control device 40 which controls the operation of the pad temperature adjusting device 5 on the basis of the temperature (hereinafter, referred to as the pad surface temperature) of the polishing surface of the polishing pad 3 measured by the pad temperature measuring device 10. In this embodiment, the control device 40 is configured to control the operation of the entire polishing apparatus including the pad temperature adjusting device 5.

The polishing head 1 is movable in the vertical direction and is rotatable in the direction indicated by an arrow about its axis. The wafer W is held on the lower surface of the polishing head 1 by vacuum suction or the like. A motor (not shown) is connected to the polishing table 2 and is rotatable in a direction indicated by an arrow. As shown in FIG. 1, the polishing head 1 and the polishing table 2 rotate in the same direction. The polishing pad 3 is attached to the upper surface of the polishing table 2.

Polishing of the wafer W is executed as below. The wafer W to be polished is held by the polishing head 1 and is further rotated by the polishing head 1. On the other hand, the polishing pad 3 rotates together with the polishing table 2. In this state, the polishing liquid is supplied from the polishing liquid supply nozzle 4 to the surface of the polishing pad 3 and further the surface of the wafer W is pressed against the surface (that is, the polishing surface) of the polishing pad 3 by the polishing head 1. The surface of the wafer W is polished by sliding contact with the polishing pad 3 in the presence of the polishing liquid. The surface of the wafer W is flattened by the chemical action of the polishing liquid and the mechanical action of the abrasive grains contained in the polishing liquid.

The pad temperature adjusting device 5 includes a heating mechanism 9 which heats the polishing surface of the polishing pad 3 and the heating mechanism 9 includes at least a pad heater 11 which is disposed above the polishing pad 3 and a heating fluid supply system 30 which supplies a heating fluid to the pad heater 11. When the heating fluid supplied to the pad heater 11 through the heating fluid supply system 30 is injected to the polishing surface of the polishing pad 3, the polishing surface can be heated to a predetermined target temperature and maintained at the target temperature.

Further, the pad temperature adjusting device 5 shown in FIG. 1 includes a cooling mechanism 50 which injects a fluid to the polishing surface of the polishing pad 3 to cool the polishing surface and a suction mechanism 60 which is disposed above the polishing surface of the polishing pad 3.

The cooling mechanism 50 includes at least a pad cooler 51 which is disposed above the polishing pad 3 and a cooling fluid supply system 52 which supplies a cooling fluid to the pad cooler 51. The suction mechanism 60 includes at least a suction nozzle 61 which is disposed above the polishing pad 3, a vacuum source (vacuum device) 63, and a suction line 62 which connects the vacuum source 63 to the suction nozzle 61. Examples of the vacuum source 63 include suction pumps, suction fans, and ejectors. The suction mechanism 60 may include a flow rate regulator 64 which is disposed in the suction line 62. The flow rate regulator 64 is, for example, a damper.

The pad temperature measuring device 10 measures the pad surface temperature in a non-contact manner and sends the measurement value to the control device 40. The pad temperature measuring device 10 may be an infrared thermometer or thermocouple thermometer which measures the surface temperature of the polishing pad 3 and may be a temperature distribution measuring device which acquires the temperature distribution (temperature profile) of the polishing pad 3 in the radial direction of the polishing pad 3. Examples of the temperature distribution measuring device include thermography, thermopile, and infrared cameras. When the pad temperature measuring device 10 is the temperature distribution measuring device, the pad temperature measuring device 10 is configured to measure the distribution of the surface temperature of the polishing pad 3 in a region including the center and the outer peripheral edge of the polishing pad 3 and a region extending in the radial direction of the polishing pad 3. In the present specification, the temperature distribution (temperature profile) indicates the relationship between the pad surface temperature and the radial position on the wafer W.

The control device 40 controls the operation of the pad temperature adjusting device 5 on the basis of the measured pad surface temperature so that the pad surface temperature is maintained at a predetermined target temperature. Hereinafter, an example in which the heating fluid supplied from the heating fluid supply system 30 to the pad heater 11 is the superheated steam will be described. However, the heating fluid is not limited to this example. The heating fluid may be a hot gas (for example, hot air, nitrogen, or argon) or heated steam. Additionally, the superheated steam means high-temperature steam obtained by further heating saturated steam.

Further, hereinafter, an example in which the cooling fluid is a room-temperature gas (for example, an inert gas such as nitrogen or argon) will be described. However, the cooling fluid is not limited to this example. The cooling fluid may be a gas cooled to a set temperature lower than a room temperature or a gas heated from a room temperature to a set temperature lower than the target temperature of the polishing pad 3. The cooling fluid is preferably an inert gas in consideration of the influence on the polishing liquid. However, the cooling fluid may be a gas different from the inert gas such as air.

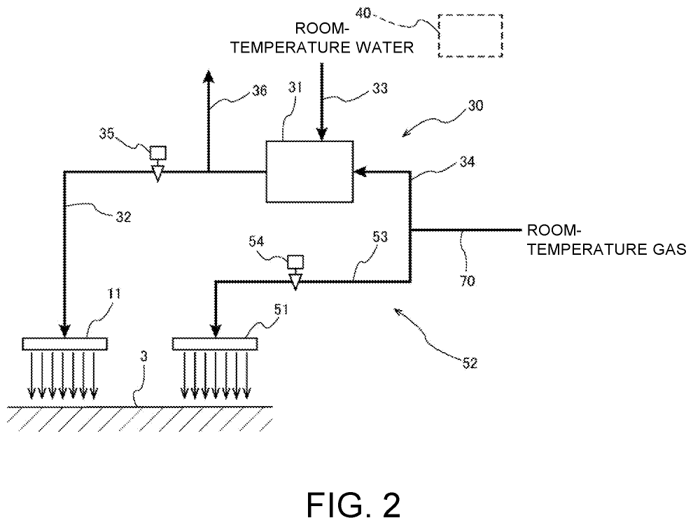

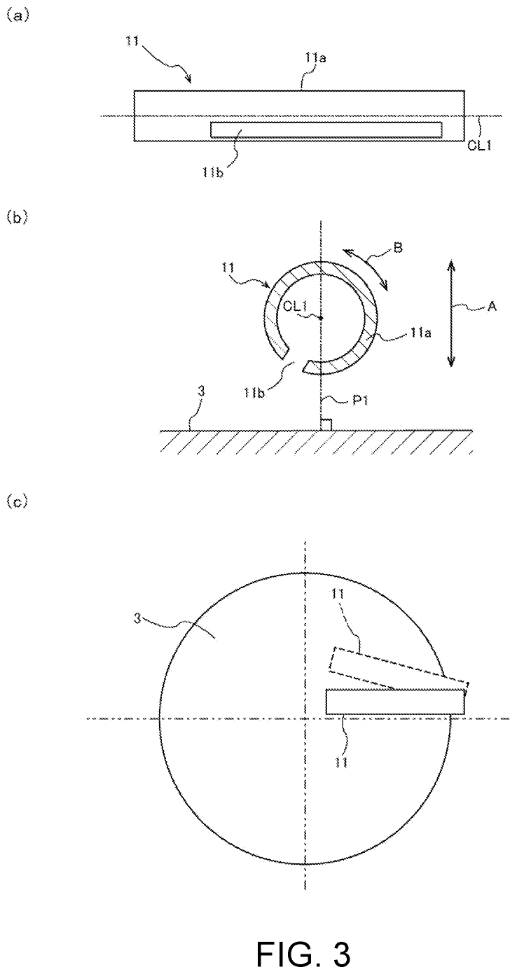

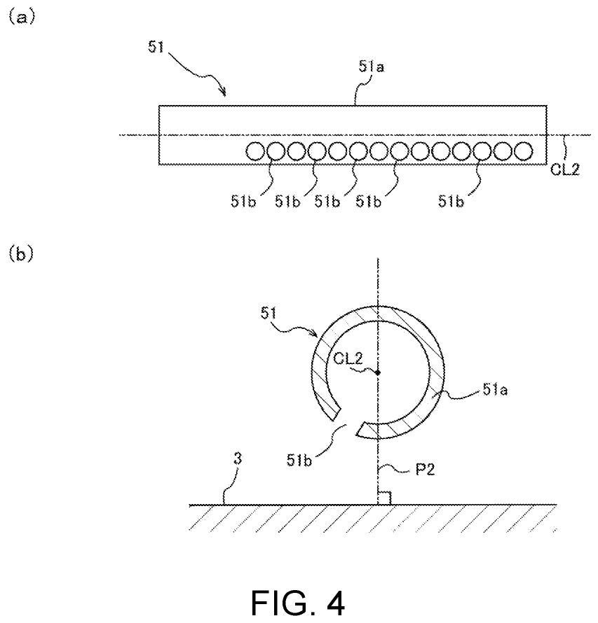

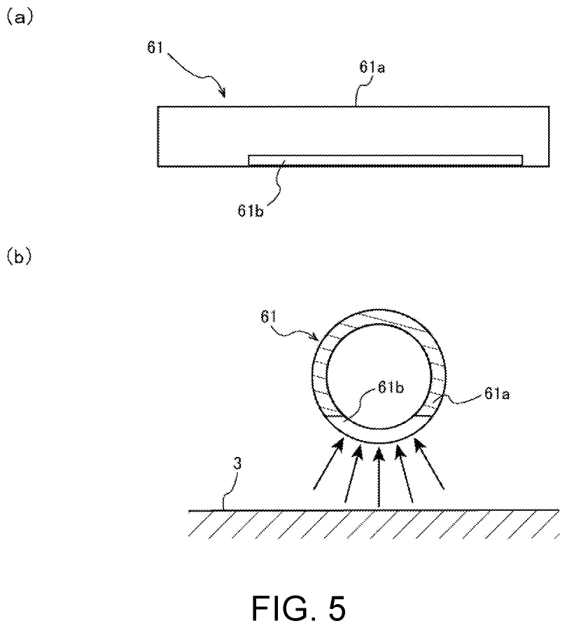

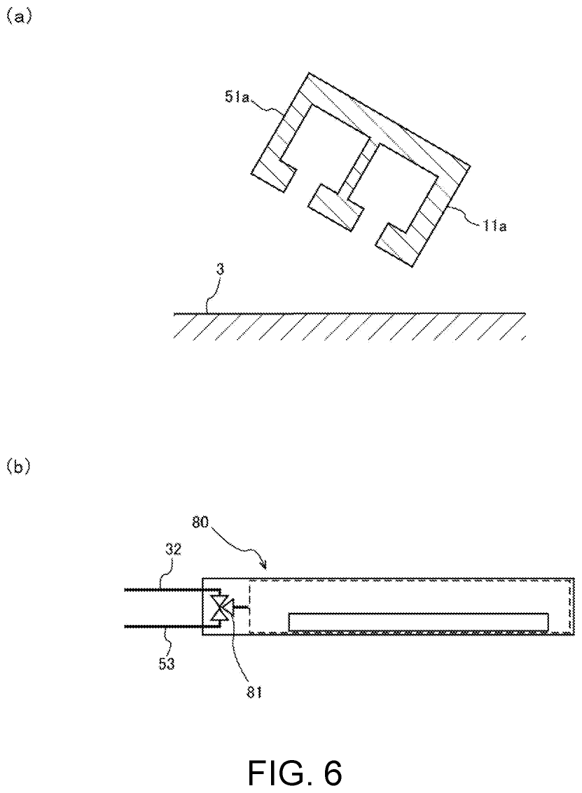

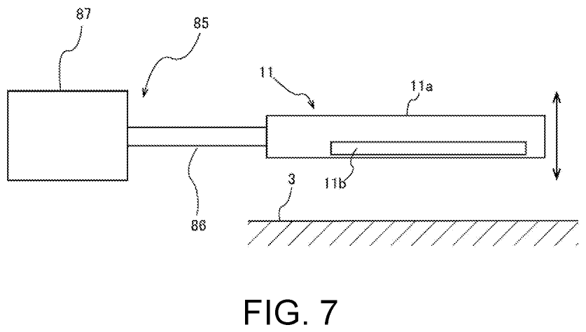

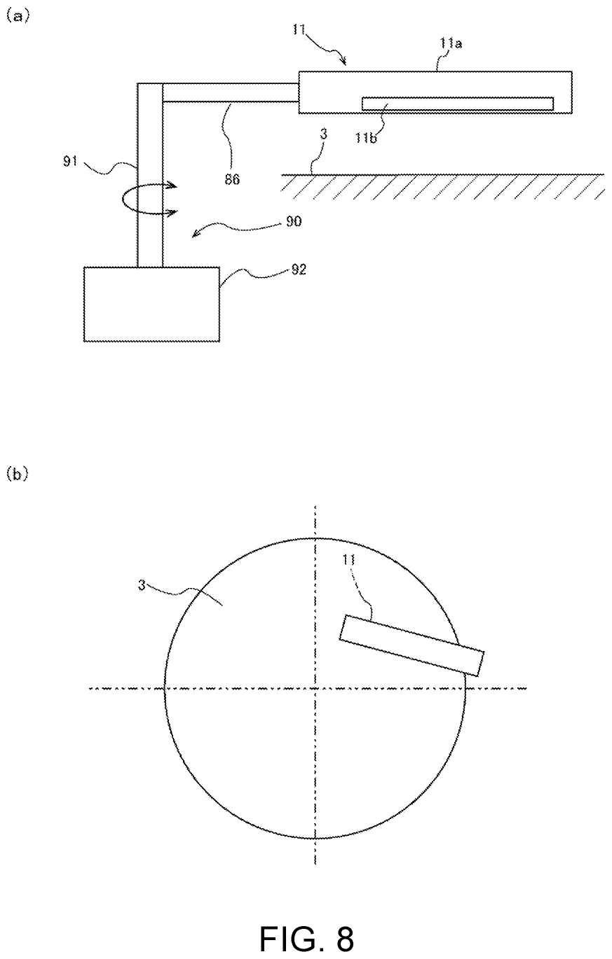

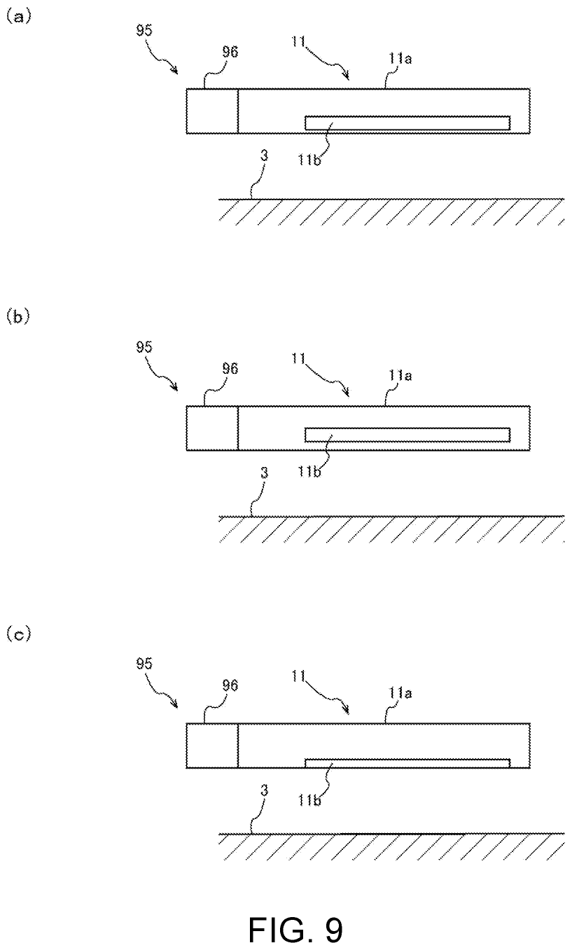

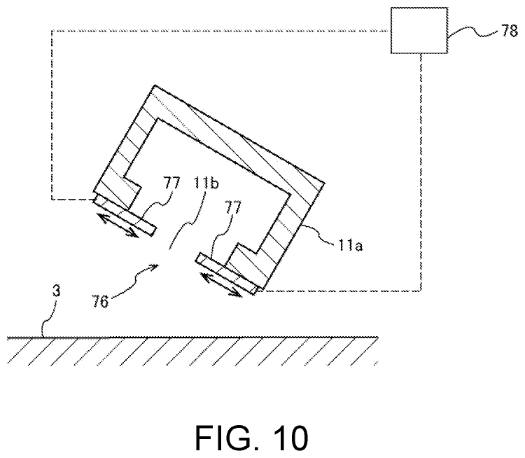

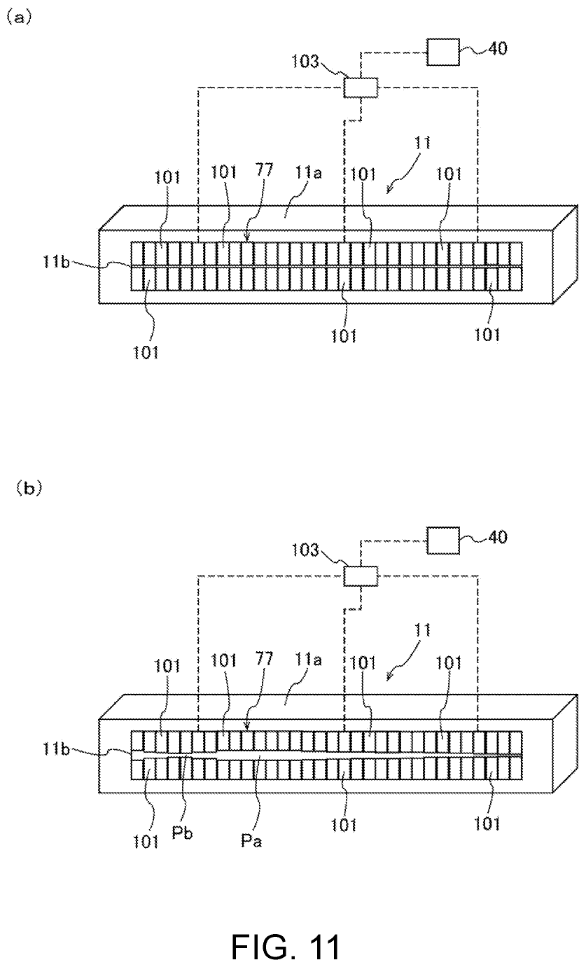

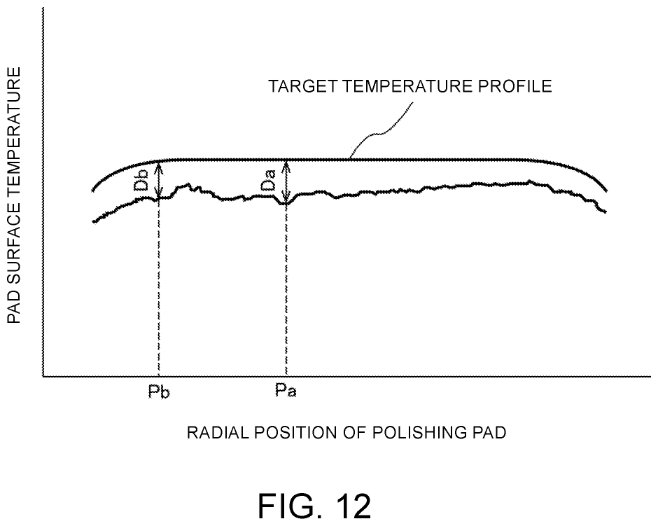

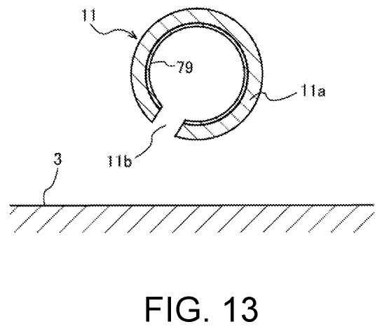

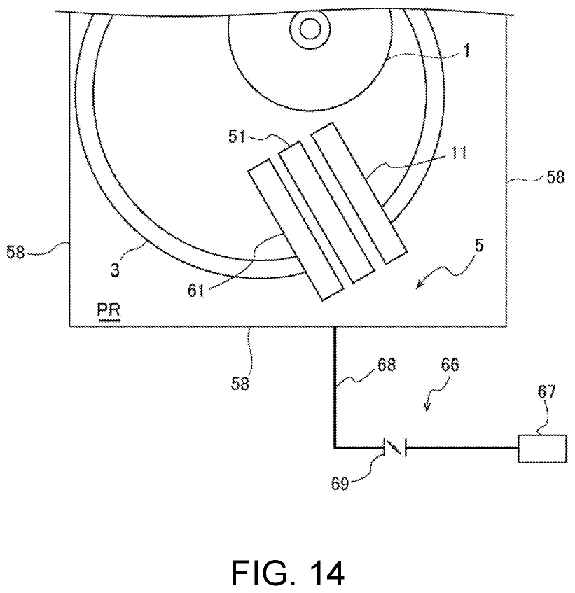

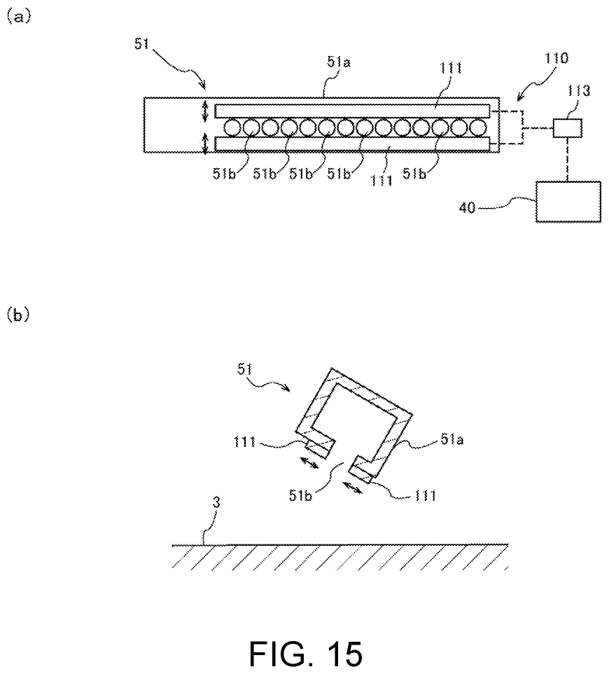

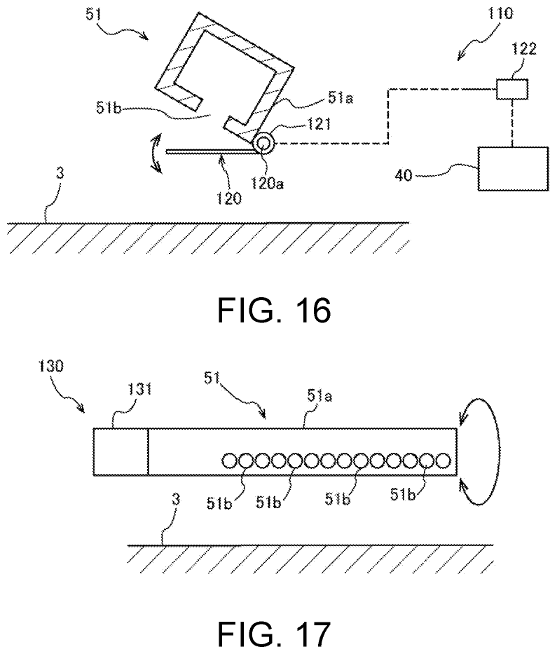

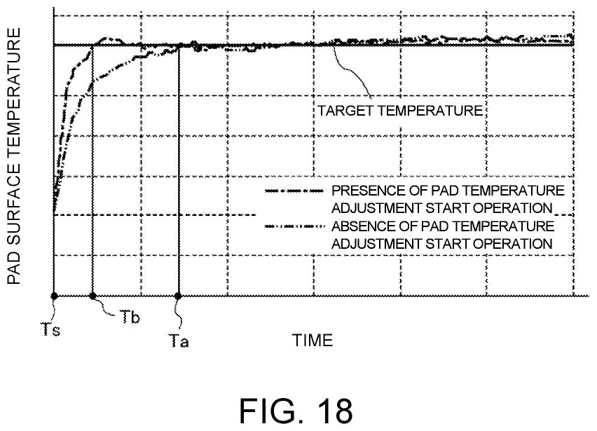

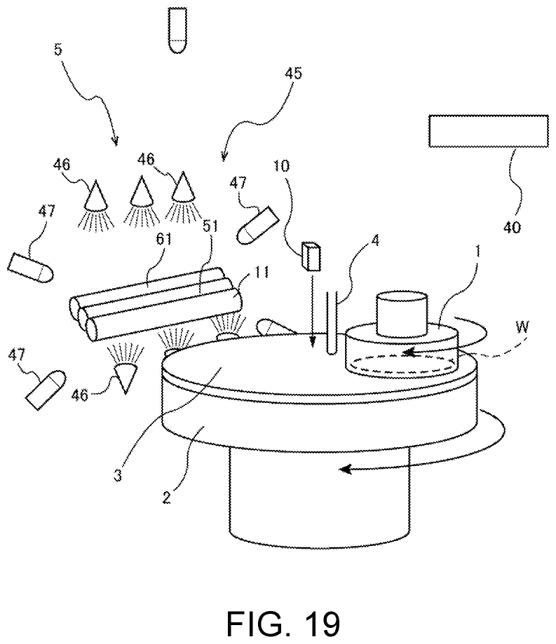

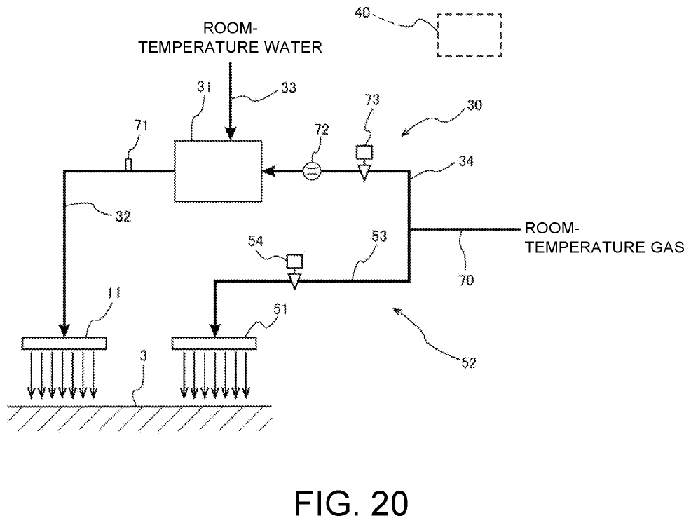

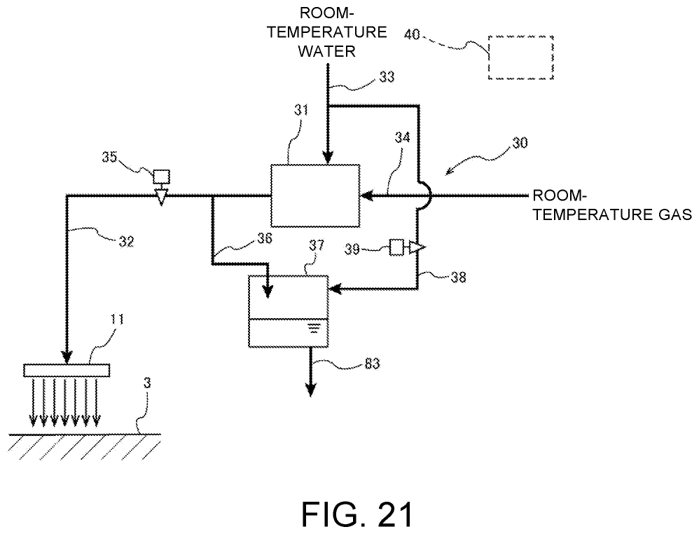

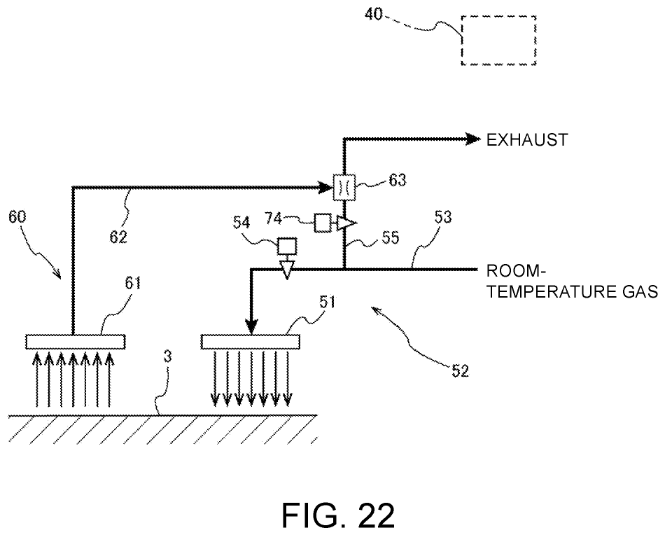

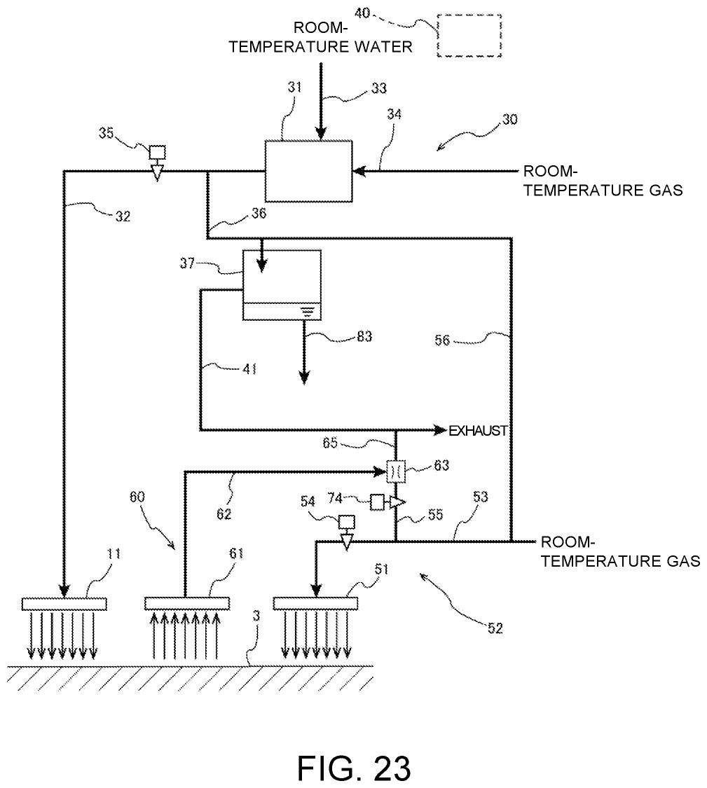

FIG. 2 is a schematic view showing the heating fluid supply system and the cooling fluid supply system according to an embodiment.

The heating fluid supply system 30 shown in FIG. 2 includes a superheated steam generator 31, a superheated steam supply line 32 which extends from the superheated steam generator 31 to the pad heater 11, a water supply line 33 which supplies water to the superheated steam generator 31, and a gas supply line 34 which supplies a room-temperature gas to the superheated steam generator 31. The gas supply line 34 branches from a gas main line 70 extending from a gas supply source (not shown) and extends to the superheated steam generator 31.

The superheated steam generator 31 mixes the water supplied from the water supply line 33 with the room-temperature gas supplied from the gas supply line 34 to generate superheated steam adjusted to a predetermined temperature. The superheated steam is supplied to the pad heater 11 through the superheated steam supply line 32 and is injected from the pad heater 11 to the polishing surface of the polishing pad 3. With this operation, it is possible to increase the temperature of the polishing surface of the polishing pad 3.

The heating fluid supply system 30 shown in FIG. 2 further includes a flow rate regulator (first flow rate regulator) 35 which is disposed in the superheated steam supply line 32 and an exhaust line 36 which branches from the superheated steam supply line 32 on the upstream side of the flow rate regulator 35. Examples of the flow rate regulator 35 include a mass flow controller and a flow rate adjusting valve. The flow rate of the superheated steam supplied to the pad heater 11 can be adjusted by the flow rate regulator 35. The excess superheated steam is discharged from the polishing apparatus through the exhaust line 36.

In an embodiment, the heating fluid supply system 30 may include an opening and closing valve (not shown) instead of the flow rate regulator 35. In this case, when the opening and closing valve of the control device 40 is opened, a predetermined flow rate of superheated steam (heating fluid) is supplied to the pad heater 11 and is injected from the pad heater 11 to the polishing surface of the polishing pad 3.

When the high-temperature gas is used as the heating fluid instead of the superheated steam, in the heating fluid supply system 30, the water supply line 33 may be omitted and the superheated steam generator 31 may be replaced with a heating gas heater. Further, the superheated steam supply line 32 is read as a heating gas supply line.

The cooling fluid supply system 52 shown in FIG. 2 includes a cooling gas supply line 53 which branches from the gas main line 70 and extends to the pad cooler 51 and a flow rate regulator (second flow rate regulator) 54 which is disposed in the cooling gas supply line 53. Examples of the flow rate regulator 54 include a mass flow controller and a flow rate adjusting valve. The flow rate of the cooling gas supplied to the pad cooler 51 can be adjusted by the flow rate regulator 54. The cooling fluid is supplied to the pad cooler 51 through the cooling gas supply line 53 and is injected from the pad cooler 51 to the polishing surface of the polishing pad 3. With this operation, it is possible to decrease the temperature of the polishing surface of the polishing pad 3.

In an embodiment, the cooling fluid supply system 52 may include an opening and closing valve (not shown) instead of the flow rate regulator 54. In this case, when the control device 40 opens the opening and closing valve, a predetermined flow rate of a cooling gas (cooling fluid) is supplied to the pad cooler 51 and is injected from the pad cooler 51 to the polishing surface of the polishing pad 3.

The control device 40 is connected to the superheated steam generator 31, the flow rate regulators 35 and 54, the vacuum source 63, and the flow rate regulator 64 (see FIG. 1). The control device 40 controls the operation of at least one of the superheated steam generator 31, the flow rate regulators 35 and 54, the vacuum source 63, and the flow rate regulator 64 on the basis of the measurement value of the pad temperature measuring device 10 so that the pad surface temperature matches a predetermined target temperature. For example, the control device 40 adjusts the flow rate of the superheated steam and the flow rate of the cooling gas by controlling the operations of the flow rate regulators 35 and 54 so that the pad surface temperature matches a predetermined target temperature.

The control device 40 may control at least one of the operation of the superheated steam generator 31, the operation of the vacuum source 63, and the operation of the flow rate regulator 64 in addition to or instead of the operations of the flow rate regulators 35 and 54. For example, the control device 40 may adjust the temperature of the superheated steam generated by the superheated steam generator 31 and may control the operation of the vacuum source 63 and/or the flow rate regulator 64 to adjust the amount of sucked air. The temperature of the polishing surface can be adjusted by changing the temperature of the superheated steam injected to the polishing surface of the polishing pad 3. When the amount of sucked air is increased or decreased by the vacuum source 63 and/or the flow rate regulator 64, the amount of heat of vaporization taken from the slurry on the polishing surface changes, so that the temperature of the polishing surface can be adjusted.

In an embodiment, the suction mechanism 60 may be used as an auxiliary cooling mechanism of the cooling mechanism 50 or the cooling mechanism 50 may be omitted by controlling the operation of the vacuum source 63 and/or the flow rate regulator 64 of the suction mechanism 60 to increase the amount of air sucked from the suction nozzle 61.

The pad temperature measuring device 10 (see FIG. 1) measures the pad surface temperature in a non-contact manner and sends the measurement value to the control device 40. In this embodiment, the control device 40 PID controls the operation amount of at least one of the superheated steam generator 31, the flow rate regulators 35 and 54, the vacuum source 63, and the flow rate regulator 64 on the basis of the measured pad surface temperature so that the pad surface temperature is maintained at a predetermined target temperature.

The temperature adjustment method for the polishing surface of the polishing pad 3 using the control device 40 is not limited to the PID control as long as the measured pad surface temperature is maintained at the target temperature and an arbitrary control method can be used. For example, the control device 40 may have an artificial intelligence (AI) function of conducting prediction or determination using a trained model constructed by machine learning at least one of the operation amounts of the superheated steam generator 31, the flow rate regulators 35 and 54, the vacuum source 63, and the flow rate regulator 64.

(a) of FIG. 3 is a schematic view showing the pad heater according to an embodiment, (b) of FIG. 3 is a cross-sectional view of the pad heater shown in (a) of FIG. 3, and (c) of FIG. 3 is a plan view showing an example of the arrangement of the pad heater with respect to the polishing pad 3. As shown in (a) to (c) of FIG. 3, the pad heater 11 includes a longitudinal portion 11a which extends in the substantially radial direction of the polishing pad 3 and an injection port 11b which injects the heating fluid toward the polishing surface of the polishing pad 3. A superheated steam flow path (not shown) is formed inside the longitudinal portion 11a. The longitudinal portion 11a of the pad heater 11 preferably extends in parallel to the polishing surface.

The injection port 11b has a slit shape which is formed in the longitudinal direction of the longitudinal portion 11a. It is preferable that the injection port 11b faces obliquely with respect to a virtual plane P1 extending in a vertical direction with respect to the polishing surface of the polishing pad 3 along a center axis CL1 of the longitudinal portion 11a so that the heating fluid obliquely collides with the polishing surface of the polishing pad 3.

The shape of the longitudinal portion 11a is arbitrary as long as the heating fluid can be injected from the injection port 11b toward the polishing surface of the polishing pad 3. For example, the longitudinal portion 11a may have a cylindrical shape or may have a polygonal cylinder shape such as a square cylinder shape or a pentagonal cylinder shape.

(a) of FIG. 4 is a schematic view of the pad cooler according to an embodiment and (b) of FIG. 4 is a cross-sectional view of the pad cooler shown in (a) of FIG. 4. The pad cooler 51 shown in (a) and (b) of FIG. 4 includes a longitudinal portion 51a which extends in the substantially radial direction of the polishing pad 3 and a plurality of injection ports 51b which injects the cooling fluid toward the polishing surface of the polishing pad 3. A cooling gas flow path (not shown) is formed inside the longitudinal portion 51a. The longitudinal portion 51a of the pad cooler 51 preferably extends in parallel to the polishing surface.

The plurality of injection ports 51b is arranged in the longitudinal direction of the longitudinal portion 51a. In this embodiment, each injection port 51b has a circular shape. It is preferable that the injection port 51b faces obliquely with respect to a plane P2 extending in the vertical direction with respect to the polishing surface of the polishing pad 3 along a center axis CL2 of the longitudinal portion 51a so that the cooling fluid obliquely collides with the polishing surface of the polishing pad 3.

The shape of the longitudinal portion 51a is arbitrary as long as the cooling fluid can be injected from the injection port 51b toward the polishing surface of the polishing pad 3. For example, the longitudinal portion 51a may have a cylindrical shape or may have a polygonal cylinder shape such as a square cylinder shape or a pentagonal cylinder shape. Further, the number and shape of the injection port 51b are arbitrary. For example, the injection port 51b may be one opening formed in the longitudinal direction of the longitudinal portion 51a and having a slit shape and each of the plurality of injection ports 51b may have a square shape or a triangular shape.

(a) of FIG. 5 is a schematic view of the suction nozzle according to an embodiment and (b) of FIG. 5 is a cross-sectional view of the suction nozzle shown in (a) of FIG. 5. The suction nozzle 61 shown in (a) and (b) of FIG. 5 includes a longitudinal portion 61a which extends in the substantially radial direction of the polishing pad 3 and a suction port 61b which sucks air above the polishing surface of the polishing pad 3. The suction port 61b preferably faces the polishing surface. A sucked air flow path (not shown) is formed inside the longitudinal portion 61a. The longitudinal portion 61a of the suction nozzle 61 preferably extends in parallel to the polishing surface.

As long as a desired amount of air can be sucked from the suction nozzle 61, the shape of the suction nozzle 61 is arbitrary and the number and shape of the suction port 61b are also arbitrary. For example, the suction mechanism 60 may include a plurality of the suction ports 61b arranged in the longitudinal direction of the longitudinal portion 61a. In this case, each suction port 61b may have a circular shape or may have a square shape or a triangular shape. Although not shown in the drawings, the suction nozzle 61 may have a tip portion having a dome shape. In this case, an opening formed at the lowest portion of the dome-shaped tip portion of the suction nozzle 61 functions as the suction port 61b. Further, the dome-shaped tip portion of the suction nozzle 61 may accommodate the longitudinal portion 11a of the pad heater 11 and/or the longitudinal portion 51b of the pad cooler 51.

As shown in (a) of FIG. 6, the longitudinal portion 11a of the pad heater 11 and the longitudinal portion 51b of the pad cooler 51 may be integrally formed with each other. Alternatively, as shown in (b) of FIG. 6, the pad temperature adjusting device 5 may include a common longitudinal portion 80 which functions as both the longitudinal portion 11a of the pad heater 11 and the longitudinal portion 51b of the pad cooler 51. In this case, the superheated steam supply line 32 and the cooling gas supply line 53 are connected to the common longitudinal portion 80 through a mixing valve 81. When the control device 40 adjusts the valve opening degree of the mixing valve 81, a mixed gas of the superheated steam and the cooling gas having a desired temperature is supplied to the common longitudinal portion 80 and is injected from the longitudinal portion 80 toward the polishing surface of the polishing pad 3. For example, a slit-shaped injection port is formed in the longitudinal portion 80 in the longitudinal direction of the longitudinal portion 80.

When the pad temperature adjusting device 5 includes the mixing valve 81, the control device 40 is configured to calculate the operation amount of the mixing valve 81 necessary to eliminate the difference between the predetermined target temperature and the surface temperature of the polishing pad 3. The valve opening degree of the mixing valve 81 corresponds to the mixing ratio between the superheated steam and the cooling gas. The control device 40 adjusts the mixing ratio between the superheated steam and the cooling gas by changing the operation amount of the mixing valve 81, so that the temperature of the mixed gas injected from the injection port of the longitudinal portion 80 to the polishing pad 3 is adjusted. The control device 40 controls the operation amount of the mixing valve 81 (that is, the valve opening degree of the mixing valve 81) so that the surface temperature of the polishing pad 3 matches the predetermined target temperature.

The arrangement order of the pad heater 11, the pad cooler 51, and the suction nozzle 61 is arbitrary. However, as shown in FIG. 1, it is preferable that the pad cooler 51 is disposed on the downstream side of the pad heater 11 in the rotation direction of the polishing pad 3 and the suction nozzle 61 is disposed on the downstream side of the pad cooler 51 in the rotation direction of the polishing pad 3. In this case, the pad cooler 51 is located between the pad heater 11 and the suction nozzle 61.

Further, the pad heater 11, the pad cooler 51, and the suction nozzle 61 are preferably arranged adjacent to each other. In this case, the pad heater 11, the pad cooler 51, and the suction nozzle 61 may be connected to each other by a connecting tool such as a connecting bar, a connecting block, or a connecting arm (none of which is shown). The connecting tool may function as a base for integrating the pad heater 11, the pad cooler 51, and the suction nozzle 61 into an integral structure.

According to this embodiment, the pad heater 11, the pad cooler 51, and the suction nozzle 61 are arranged above the polishing pad 3. That is, the pad temperature adjusting device 5 does not have a component to which dirt such as abrasive grains contained in the polishing liquid and abrasion powder of the polishing pad 3 adheres. As a result, defects such as scratches and contamination caused by the dirt that has fallen off from the pad temperature adjusting device 5 do not occur on the wafer W. Further, since the surface state of the polishing pad 3 does not change due to the dirt fallen off from the pad temperature adjusting device 5, the wafer W can be polished at a desired polishing rate.

As shown in FIG. 7, the pad temperature adjusting device 5 may include a vertical movement mechanism 85 which moves the pad heater 11 upward and downward with respect to the polishing surface of the polishing pad 3. FIG. 7 is a schematic view showing an example of the vertical movement mechanism 85.

The vertical movement mechanism 85 shown in FIG. 7 includes a support arm 86 which is connected to the pad heater 11 and a vertical movement actuator 87 which moves the pad heater 11 upward and downward through the support arm 86. The configuration of the vertical movement actuator 87 is arbitrary as long as the pad heater 11 can be moved in the up and down direction. For example, the vertical movement actuator 87 may be a piston cylinder device which includes a piston for moving the pad heater 11 upward and downward through the support arm 86 or a motor (for example, a servo motor or a stepping motor) which moves the pad heater 11 upward and downward through the support arm 86. In an embodiment, the vertical movement actuator 87 may be a piezo actuator which moves the pad heater 11 upward and downward through the support arm 86 by using the piezoelectric effect of the piezo element.

The vertical movement mechanism 85 is connected to the control device 40. The control device 40 controls the operation of the vertical movement mechanism 85 (that is, the operation amount of the vertical movement actuator 87) on the basis of the measurement value of the pad temperature measuring device 10, so that the position of the pad heater 11 in the up and down direction with respect to the polishing surface of the polishing pad 3 changes (see an arrow A of (b) of FIG. 3). When the distance between the pad heater 11 and the polishing pad 3 changes, the temperature of the superheated steam when colliding with the polishing surface of the polishing pad 3 changes. For example, when the pad heater 11 is moved close to the polishing pad 3, superheated steam having a high temperature collides with the polishing surface of the polishing pad 3 so that the pad surface temperature can be increased. On the other hand, when the pad heater 11 is moved away from the polishing pad 3, superheated steam having a low temperature collides with the polishing surface of the polishing pad 3 so that the pad surface temperature can be decreased. Thus, it is possible to adjust the pad surface temperature by changing the distance between the pad heater 11 and the polishing surface of the polishing pad 3.

Further, as shown in (a) of FIG. 8, the pad temperature adjusting device 5 may include a rotating mechanism 90 which rotates the pad heater 11 in a horizontal direction with respect to the polishing surface of the polishing pad 3. (a) of FIG. 8 is a schematic view showing an example of the rotating mechanism 90 and (b) of FIG. 8 is a plan view showing the pad heater 11 rotated by the rotating mechanism 90.

The rotating mechanism 90 shown in (a) of FIG. 8 includes a rotating shaft 91 which is connected to the pad heater 11 through the support arm 86 and a rotation actuator 92 which rotates the rotating shaft 91. The rotation actuator 92 is, for example, a motor (for example, a servo motor or a stepping motor) that rotates the rotating shaft 91 or a rotary cylinder. In an embodiment, the rotation actuator 92 may be a piston cylinder including a piston. In this case, the rotating mechanism 90 includes a link mechanism which converts the operation of the piston of the piston cylinder into the rotation operation of the rotating shaft 91.

The rotating mechanism 90 is connected to the control device 40. The control device 40 controls the operation of the rotating mechanism 90 (that is, the operation amount of the rotation actuator 92) on the basis of the measurement value of the pad temperature measuring device 10, so that the rotation angle of the pad heater 11 with respect to the polishing surface of the polishing pad 3 is controlled.

As shown in (b) of FIG. 8, when the pad heater 11 is rotated from the initial position (see (c) of FIG. 3) in which the longitudinal portion 11a of the pad heater 11 extends substantially in parallel to the longitudinal direction of the polishing pad 3, the direction and amount of the superheated steam colliding with the polishing surface of the polishing pad 3 change. As a result, it is possible to adjust the pad surface temperature by controlling the rotation angle of the pad heater 11 from the initial position.

(a) of FIG. 9 is a schematic view showing an example of a rotation mechanism 95 which rotates the pad heater 11 about its longitudinal axis, (b) of FIG. 9 is a cross-sectional view showing a state in which the pad heater 11 shown in (a) of FIG. 9 is rotated upward, and (c) of FIG. 9 is a cross-sectional view showing a state in which the pad heater 11 shown in (a) of FIG. 9 is rotated downward.

The rotation mechanism 95 shown in (a) of FIG. 9 is configured as a rotation actuator 96 which is attached to the end of the pad heater 11 and rotates the pad heater 11. The rotation actuator 96 is, for example, a servo motor or a stepping motor.

The rotation mechanism 95 is connected to the control device 40. The control device 40 controls the operation of the rotation mechanism 95 (that is, the operation amount of the rotation actuator 96) on the basis of the measurement value of the pad temperature measuring device 10, so that the direction of the injection port 11b of the pad heater 11 with respect to the polishing surface of the polishing pad 3 changes (see an arrow B of (b) of FIG. 3).

When the direction of the injection port 11b of the pad heater 11 with respect to the polishing surface of the polishing pad 3 is changed as shown in (b) and (c) of FIG. 9, the amount and the temperature of the superheated steam colliding with the polishing surface of the polishing pad 3 change. When the pad heater 11 is rotated upward as shown in (b) of FIG. 9, the amount and the temperature of the superheated steam colliding with the polishing surface of the polishing pad 3 decrease, so that the pad surface temperature can be decreased. When the pad heater 11 is rotated downward as shown in (c) of FIG. 9, the amount and the temperature of the superheated steam colliding with the polishing surface of the polishing pad 3 increase, so that the pad surface temperature can be increased. Thus, it is possible to adjust the pad surface temperature by controlling the rotation angle of the pad heater 11 with respect to the support arm 86.

The pad temperature adjusting device 5 may have any two combinations of the vertical movement mechanism 85, the rotating mechanism 90, and the rotation mechanism 90 or may have all of the vertical movement mechanism 85, the rotating mechanism 90, and the rotation mechanism 90.

FIG. 10 is a cross-sectional view schematically showing a pad heater according to another embodiment. The pad heater 11 shown in FIG. 10 further includes a shutter mechanism 76 having a shutter 77 opening and closing the injection port 11b and an actuator 78 driving the shutter 77. In the example shown in FIG. 10, the shutter mechanism 76 includes two shutters 77, but may include only one shutter 77. The actuator 78 may be, for example, a piston cylinder device including a piston which moves the shutter 77 or a motor (for example, a servo motor or a stepping motor) which moves the shutter 77. In an embodiment, the actuator 78 may be a piezo actuator which moves the shutter 77 by using the piezoelectric effect of the piezo element.

The actuator 78 is connected to the control device 40. The control device 40 controls the operation of the actuator 78 (that is, the operation amount of the actuator 78) on the basis of the measurement value of the pad temperature measuring device 10, so that the opening degree of the injection port 11b is controlled. In this embodiment, the opening degree of the injection port 11b corresponds to the size of the width of the injection port 11b in the direction perpendicular to the longitudinal direction. When the opening degree of the injection port 11b is changed, the flow velocity and the temperature of the superheated steam colliding with the polishing surface of the polishing pad 3 change and the pad surface temperature changes. Thus, it is possible to adjust the pad surface temperature by controlling the opening degree of the injection port 11b.

(a) and (b) of FIG. 11 are views schematically showing a shutter mechanism according to another embodiment. More specifically, (a) of FIG. 11 is a perspective view of the shutter mechanism according to another embodiment as viewed from a lower surface side and (b) of FIG. 11 is a schematic view showing an example of the operation of the shutter mechanism shown in (a) of FIG. 11. Since a configuration particularly not described in this embodiment is the same as that of the embodiment described with reference to FIG. 10, the duplicated description thereof will be omitted.

The shutter mechanism 76 shown in (a) of FIG. 11 includes the shutter 77 having a plurality of piezo elements 101. The plurality of piezo elements 101 is arranged in the longitudinal direction of the injection port 11b (that is, the longitudinal direction of the longitudinal portion 11a). In this embodiment, the longitudinal portion 11a of the pad heater 11 has a rectangular cross-section, but as described above, the cross-sectional shape of the longitudinal portion 11a is not limited to this example. The shutter 77 shown in (a) of FIG. 11 adjusts the opening degree of the injection port 11b of the pad heater 11 by the expansion and contraction operation due to the inverse piezoelectric effect of the piezo element.

Each piezo element 101 is connected to the piezo element driver 103 and the piezo element driver 103 is connected to the control device 40. In (a) of FIG. 11, only control lines extending from some piezo elements 101 to the piezo element driver 103 are drawn in order to prevent the figure from becoming complicated. The control device 40 can independently control the expansion and contraction operation of each piezo element 101 by controlling the operation of the piezo element driver 103 (for example, see (b) of FIG. 11). The piezo element driver 103 functions as an actuator which adjusts the opening degree of the injection port 11b of the pad heater 11.

When the pad temperature measuring device 10 is the temperature distribution measuring device, the control device 40 can acquire the temperature distribution (temperature profile) of the polishing pad 3 in the radial direction of the polishing pad 3. FIG. 12 is a graph showing an example of the target temperature profile of the polishing pad and the temperature profile acquired by the pad temperature measuring device. In FIG. 12, the vertical axis indicates the pad surface temperature and the horizontal axis indicates the radial position of the polishing pad.

In order to precisely control the in-plane uniformity (flatness) of the entire surface of the wafer W subjected to polishing, it is preferable to always match the temperature profile with the target temperature. Therefore, in this embodiment, the control device 40 controls the expansion and contraction operation of each piezo element 101 so that the temperature profile acquired by the pad temperature measuring device 10 matches the target temperature. For example, as shown in FIG. 12, the control device 40 increases the injection amount of the superheated steam by largely contracting the piezo element 101 corresponding to the position Pa of the polishing pad 3 having a large difference Da between the target temperature and the measurement temperature. On the other hand, the control device 40 decreases the expansion and contraction amount of the piezo element 101 corresponding to the position Pb of the polishing pad 3 having a small difference Db between the target temperature and the measurement temperature so that the injection amount of the superheated steam becomes smaller than the injection amount at the position Pa.

The control device 40 controls the operation of the piezo element driver 103 (that is, the expansion and contraction amount of each piezo element 101) on the basis of the measurement value of the pad temperature measuring device 10, so that the opening degree of the injection port 11b in the radial direction of the polishing pad 3 is freely controlled. When the opening degree of the injection port 11b is changed as described above, the flow velocity and the temperature of the superheated steam colliding with the polishing surface of the polishing pad 3 change and the pad surface temperature changes. By performing such pad temperature control the temperature profile of the entire polishing pad 3 can match the target temperature. As a result, it is possible to precisely polish the wafer W.

FIG. 13 is a cross-sectional view schematically showing the pad heater 11 according to still another embodiment. FIG. 13 shows a cross-section of the longitudinal portion 11a of the pad heater 11. The pad heater 11 shown in FIG. 13 includes a heater 79 disposed inside the longitudinal portion 11a. The heater 79 is also connected to the control device 40 and the control device 40 controls the operation (for example, ON/OFF operation) of the heater 79. The heater 79 can reheat the superheated steam which is cooled while flowing from the superheated steam generator 31 to the pad heater 11. By reheating the superheated steam, problems such as dew condensation of the superheated steam on the pad heater 11 are prevented.

FIG. 14 is a schematic view showing a polishing apparatus including a pad temperature adjusting device according to still another embodiment. FIG. 14 corresponds to a plan view of the polishing apparatus. Since a configuration particularly not described in this embodiment is the same as that of the above-described embodiment, the duplicated description thereof will be omitted.

In the embodiment shown in FIG. 14, the polishing table 2, components such as the polishing pad 3 and the polishing head 1 are arranged in the polishing chamber PR and the wafer W is polished in the polishing chamber PR. The polishing chamber PR is a space defined by four partition walls 58 and the pressure inside the polishing chamber is maintained at a predetermined pressure (for example, a pressure lower than the outside of the polishing chamber PR). Additionally, in FIG. 14, three of four partition walls 58 are drawn.

When the superheated steam is injected from the pad heater 11 and the cooling gas is injected from the pad cooler 51, the pressure of the polishing chamber PR becomes higher than a predetermined pressure. As a result, there is a risk of exceeding a permissible value provided for the set pressure of the polishing chamber PR. Therefore, in this embodiment, the pad temperature adjusting device 5 includes a polishing chamber suction device 66 which sucks air inside the polishing chamber PR from the polishing chamber PR so that the pressure inside the polishing chamber PR is maintained at a predetermined value. The polishing chamber suction device 66 shown in FIG. 14 includes a vacuum device 67 such as a vacuum pump and a suction pump, a polishing chamber suction line 68 extending from the polishing chamber PR, and a damper 69 disposed in the polishing chamber suction line 68.

The control device 40 is connected to the damper 69 and the control device 40 adjusts the opening degree of the damper 69 so that the pressure inside the polishing chamber PR is maintained at a predetermined value. For example, the control device 40 adjusts the opening degree of the damper 69 so that the flow rate of the air flowing through the polishing chamber suction line 68 becomes the same as the total of the measurement values of the flow rate regulators 35 and 54. In an embodiment, the control device 40 may be also connected to the vacuum device 67 and control the opening degree of the damper 69 and/or the operation of the vacuum device 67 so that the pressure inside the polishing chamber PR is maintained at a predetermined value.

(a) of FIG. 15 is a schematic view showing a pad cooler of a cooling mechanism according to another embodiment and (b) of FIG. 15 is a cross-sectional view of the pad cooler shown in (a) of FIG. 15. Since a configuration particularly not described in this embodiment is the same as that of the embodiment shown in (a) and (b) of FIG. 4, the duplicated description thereof will be omitted.

The pad cooler 51 shown in (a) and (b) of FIG. 15 further includes a shutter mechanism 110 having a shutter 111 opening and closing the injection port 51b and an actuator 113 driving the shutter 111. In the example shown in FIG. 15, the longitudinal portion 51a of the pad cooler 51 has a rectangular cross-section and the shutter mechanism 110 includes a pair of shutters 111 capable of adjusting the opening degree of all injection ports 51b. In an embodiment, the shutter mechanism 110 may include only one shutter 111 capable of adjusting the opening degree of all injection ports 51b. The actuator 113 may be, for example, a piston cylinder device having a piston moving the shutter 111 or a motor (for example, a servo motor or a stepping motor) moving the shutter 111. In an embodiment, the actuator 113 may be a piezo actuator that moves the shutter 111 by using the inverse piezoelectric effect of the piezo element.

The actuator 113 is connected to the control device 40. The control device 40 controls the operation of the actuator 78 of the pad heater 11 or the operation of the piezo element driver 103 and the operation of the actuator 113 (that is, the operation amount of the injection port 51b) on the basis of the measurement value of the pad temperature measuring device 10, so that the opening degree of the injection port 11b and the injection port 51b is controlled. In this embodiment, the opening degree of the injection port 51b corresponds to the size of the width of the injection port 51b in the direction perpendicular to the longitudinal direction. When the opening degree of the injection port 11b and the injection port 51b is changed, the flow velocity and the temperature of the superheated steam colliding with the polishing surface of the polishing pad 3 and the flow velocity and the temperature of the cooling gas change and the pad surface temperature changes. Thus, it is possible to precisely adjust the pad surface temperature by controlling the opening degree of the injection port 11b and the injection port 51b.

FIG. 16 is a cross-sectional view schematically showing a pad cooler of a cooling mechanism according to still another embodiment. As shown in FIG. 16, the pad cooler 51 may include a guide plate 120 which is attached to the lower portion of the pad cooler 51. Specifically, the guide plate 120 is attached to the lower portion of the longitudinal portion 51a. The guide plate 120 may be a single plate extending over the entire longitudinal portion 51a or a plurality of plates attached to the corresponding injection ports 51b. The guide plate 120 has a shaft 120a formed at an end portion thereof and the shaft 120a is rotatably attached to a bearing 121 fixed to the lower surface of the longitudinal portion 51a. The cooling mechanism 50 further includes a rotation actuator 122 which rotates the guide plate 120 about the shaft 120a and the rotation actuator 122 is connected to the control device 40.

When the guide plate 120 is rotated, the position and amount of the cooling gas colliding with the polishing surface of the polishing pad 3 change. As a result, it is also possible to adjust the pad surface temperature by controlling the rotation angle of the guide plate 120.

When the pad cooler 51 includes the plurality of guide plates 120 attached to the corresponding injection ports 51b, the pad temperature measuring device 10 is preferably a temperature distribution measuring device capable of acquiring the temperature distribution (temperature profile) of the polishing pad 3 in the radial direction of the polishing pad 3. The control device 40 can independently control the rotation angle of each guide plate 120 on the basis of the temperature profile acquired by the pad temperature measuring device 10. That is, the control device 40 can independently control the rotation angle of each guide plate 120 so that the temperature profile of the entire polishing pad 3 matches the target temperature. As a result, it is possible to precisely polish the wafer W.

FIG. 17 is a schematic view showing a pad cooler of a cooling mechanism according to still another embodiment. As shown in FIG. 17, the pad temperature adjusting device 5 may include a rotation mechanism 130 which rotates the pad cooler 51 about its longitudinal axis.

The rotation mechanism 130 shown in FIG. 17 is configured as a rotation actuator 131 which is attached to the end of the pad cooler 51 and rotates the pad cooler 51. The rotation actuator 131 is, for example, a servo motor or a stepping motor.

The rotation mechanism 130 is connected to the control device 40. The control device 40 controls the operation of the rotation mechanism 130 (that is, the operation amount of the rotation actuator 131) on the basis of the measurement value of the pad temperature measuring device 10, so that the direction of the injection port 51b of the pad cooler 51 with respect to the polishing surface of the polishing pad 3 can change. When the direction of the injection port 51b of the pad cooler 51 with respect to the polishing surface of the polishing pad 3 is changed, the amount and the temperature of the cooling gas colliding with the polishing surface of the polishing pad 3 change. Thus, it is possible to adjust the pad surface temperature by controlling the rotation angle of the pad cooler 51 with respect to the polishing surface of the polishing pad 3.

In the pad temperature adjusting device 5 according to the above-described embodiment, the control device 40 controls the temperature of the polishing surface of the polishing pad 3 by controlling at least one of the temperature, the flow rate, the injection amount, the injection position, and the injection range of the superheated steam and the cooling gas on the basis of the measurement value of the pad temperature measuring device 10. More specifically, the control device 40 controls at least one of the operations of the flow rate regulators 35 and 54, the superheated steam generator 31, the vertical movement mechanism 85, the rotating mechanism 90, the rotation mechanisms 95 and 130, the shutter mechanisms 77 and 110, the heater 79, the mixing valve 81, and the guide plate 120 on the basis of the measurement value of the pad temperature measuring device 10 so that the temperature of the polishing surface of the polishing pad 3 is allowed to reach the target temperature and is maintained at the target temperature. Accordingly, it is possible to precisely polish the wafer W to a desired film thickness. Particularly, in the embodiment in which the shutter 77 includes the plurality of piezo elements 10 and the embodiment in which the pad cooler 51 includes the plurality of guide plates 120 attached to the corresponding injection ports 51b, the temperature profile of the entire polishing pad 3 can match the target temperature.

In an embodiment, the control device 40 may control the pad surface temperature by adjusting the flow rate and/or the temperature of the cooling gas while supplying the superheated steam adjusted to a predetermined temperature from the pad heater 11 to the polishing pad 3 at a constant flow rate.

In an embodiment, the control device 40 may temporarily increase the flow rate and/or the temperature of the superheated steam when starting the control of the surface temperature of the polishing pad 3. More specifically, the control device 40 supplies the superheated steam having a flow rate and/or a temperature larger than the flow rate and/or the temperature of the superheated steam calculated so that the surface temperature of the polishing pad 3 is allowed to reach the target temperature to the pad heater 11.

In the present specification, the control operation of temporarily increasing the flow rate and/or the temperature of the superheated steam when starting the control of the surface temperature of the polishing pad 3 is referred to as the “pad temperature adjustment start operation”. Further, in the present specification, the flow rate and the temperature of the superheated steam calculated so that the surface temperature of the polishing pad 3 is allowed to reach the target temperature are respectively referred to as the “set flow rate” and the “set temperature”.

In the pad temperature adjustment start operation, the control device 40 controls, for example, the operation of the flow rate regulator 35 so that the flow rate of the superheated steam injected from an injection port 11a of the pad heater 11 becomes higher than the set flow rate. Alternatively, in the pad temperature adjustment start operation, the control device 40 may control the operation of the superheated steam generator 31 and/or the heater 79 so that the temperature of the superheated steam injected from the injection port 11a of the pad heater 11 becomes higher than the set temperature. The control device 40 may control the operation of the flow rate regulator 35 and the operation of the superheated steam generator 31 and/or the heater 79 so that the flow rate and the temperature of the superheated steam injected from the injection port 11a of the pad heater 11 become higher than the set flow rate and the set temperature. With such an operation, it is possible to quickly allow the pad surface temperature to reach the target temperature.

FIG. 18 is a graph illustrating an example of the pad temperature adjustment start operation. In the graph shown in FIG. 18, the vertical axis indicates the pad surface temperature and the horizontal axis indicates the time. In FIG. 18, the target temperature is drawn by a horizontal solid line and a change in the pad surface temperature when the pad temperature adjustment start operation is performed is drawn by a one-dotted chain line. In FIG. 18, a curve drawn by a two-dotted chain line indicates a change in the pad surface temperature when the pad temperature adjustment start operation is not performed. A point Ts in FIG. 18 indicates a time when the pad temperature adjusting device 5 starts the temperature adjustment of the polishing pad 3.

As described above, in the pad temperature adjustment start operation, the flow rate and/or the temperature of the superheated steam is temporarily allowed to be higher than the set flow rate and/or the set temperature. In the graph shown in FIG. 18, the flow rate of the superheated steam is allowed to be higher than the set flow rate. Hereinafter, the pad temperature adjustment start operation in which the superheated steam is injected at a flow rate higher than the set flow rate will be described. The pad temperature adjustment start operation in which the superheated steam is injected at a temperature higher than the set temperature also can be performed by the same control operation.

As shown in FIG. 18, the control device 40 previously stores a set time Ta for setting the maximum execution time of the pad temperature adjustment start operation. The set flow rate and the set time Ta can be arbitrarily set. For example, the set time Ta may be obtained by an experiment in which a predetermined flow rate of superheated steam is injected from the injection port 11a of the pad heater 11 to the polishing surface of the polishing pad 3 while the pad temperature adjustment start operation is not performed. In this experiment, the time from the start of the temperature adjustment of the polishing pad 3 until the pad surface temperature reaches the target temperature is measured and the measured time is determined as the set time Ta.

The control device 40 calculates the flow rate of the superheated steam for allowing the pad surface temperature to reach the target temperature from the start of the temperature adjustment of the polishing pad 3 (that is, the time Ts) until the set time Ta. The control device 40 injects the superheated steam from the injection port 11a of the pad heater 11 at a flow rate higher than the calculated flow rate of the superheated steam in order to perform the pad temperature adjustment start operation. Accordingly, since the pad surface temperature quickly reaches the target temperature, the polishing condition of the wafer W can be allowed to quickly reach the optimum condition.

During the execution of the pad temperature adjustment start operation, the control device 40 stops the operations of the cooling mechanism 50 and the suction mechanism 60. At the time (time Tb in FIG. 18) when the pad surface temperature reaches the target temperature, the control device 40 ends the pad temperature adjustment start operation and starts the normal pad temperature adjusting control for maintaining the pad surface temperature at the target temperature. More specifically, the control device 40 starts normal control of controlling at least one of the temperature, the flow rate, the injection amount, the injection position, and the injection range of the superheated steam and the cooling gas by starting the operations of the cooling mechanism 50 and the suction mechanism 60. Accordingly, it is possible to suppress an overshoot which is a phenomenon in which the pad surface temperature exceeds the target temperature as much as possible.

Even when the pad surface temperature does not reach the target temperature and the elapse time of the pad temperature adjustment start operation measured from the time Ts reaches the set time Ta, the control device 40 starts the normal control of controlling at least one of the temperature, the flow rate, the injection amount, the injection position, and the injection range of the superheated steam and the cooling gas. In an embodiment, the control device 40 may stop the polishing process of the wafer W by determining that abnormality occurs in the pad temperature adjusting device 5.

FIG. 19 is a schematic view showing a polishing apparatus including a pad temperature adjusting device according to still another embodiment. Since a configuration particularly not described in this embodiment is the same as that of the above-described embodiment, the duplicated description thereof will be omitted.

The pad temperature adjusting device 5 shown in FIG. 19 includes a cleaning device 45 which cleans the pad heater 11, the pad cooler 51, and the suction nozzle 61 at a retreat position on the side of the polishing pad 3. The control device 40 is connected to the cleaning device 45 and controls the operation of the cleaning device 45. Additionally, in FIG. 19, only pad heater 11, the pad cooler 51, the suction nozzle 61, and the cleaning device 45 of the pad temperature adjusting device 5 are drawn and the other components are not shown.

In this embodiment, the pad temperature adjusting device 5 includes the rotating mechanism 90 and the control device 40 operates the rotation actuator 92 (see (a) of FIG. 8) of the rotating mechanism 90 so that the pad heater 11, the pad cooler 51, and the suction nozzle 61 move from the initial position shown in (c) of FIG. 3 to the retreat position shown in FIG. 19.

The cleaning device 45 includes a plurality of sprays 46 which injects a cleaning liquid (for example, pure water) to the pad heater 11, the pad cooler 51, and the suction nozzle 61 moving to the retreat position from above and below. The control device 40 injects the cleaning liquid from the spray 46 to the pad heater 11, the pad cooler 51, and the suction nozzle 61 after the pad heater 11, the pad cooler 51, and the suction nozzle 61 move to the retreat position. With this operation, dirt adhering to the pad heater 11, the pad cooler 51, and the suction nozzle 61 is cleaned.

When the pad heater 11, the pad cooler 51, and the suction nozzle 61 are cleaned completely, the control device 40 controls the operation of the rotating mechanism 90 so that the pad heater 11, the pad cooler 51, and the suction nozzle 61 move to the initial position (see (c) of FIG. 3). When droplets of the cleaning liquid fall on the polishing pad 3 from the pad heater 11, the pad cooler 51, and the suction nozzle 61 moving to the initial position, the concentration of the polishing liquid (slurry) may change. As a result, there is a risk that the polishing performance may be adversely affected. Here, in this embodiment, the cleaning device 45 may include a plurality of nozzles 47 which blows a gas (for example, air, nitrogen, or argon) onto the pad heater 11, the pad cooler 51, and the suction nozzle 61 cleaned by the cleaning liquid.

The gas blown from the nozzle 47 can blow off the cleaning liquid adhering to the pad heater 11, the pad cooler 51, and the suction nozzle 61 to dry the pad heater 11, the pad cooler 51, and the suction nozzle 61. By this drying process, it is possible to prevent droplets of the cleaning liquid from falling on the polishing pad 3 from the pad heater 11, the pad cooler 51, and the suction nozzle 61 moving to the initial position. In an embodiment, the spray 46 may have a function of blowing a gas to the pad heater 11, the pad cooler 51, and the suction nozzle 61 separately from the cleaning liquid.

In the above-described embodiment, the pad temperature adjusting device 5 includes not only the pad heater 11 but also the cooling mechanism 50 and the suction mechanism 60. However, any one or both of the pad cooler 51 and the suction nozzle 61 of the pad temperature adjusting device 5 may be omitted. When any one or both of the pad cooler 51 and the suction nozzle 61 are omitted, the pad temperature adjusting device 5 preferably includes at least one of the vertical movement mechanism 85, the rotating mechanism 90, and the rotation mechanism 95. The pad surface temperature can be finely adjusted with these mechanisms 85, 90, and 95.

FIG. 20 is a schematic view showing a heating fluid supply system and a cooling fluid supply system according to another embodiment. Since a configuration particularly not described in this embodiment is the same as that of the embodiment shown in FIG. 2, the duplicated description thereof will be omitted.

The heating fluid supply system 30 shown in FIG. 20 includes a thermometer 71 which is disposed in the superheated steam supply line 32 and a flow meter 72 and a flow rate regulator 73 (for example, a flow rate adjusting valve) which are disposed in the gas supply line 34. The thermometer 71 is connected to the control device 40 and transmits a temperature measurement value of the superheated steam to the control device 40. The flow meter 72 and the flow rate regulator 73 are also connected to the control device 40. The flow meter 72 transmits a flow rate measurement value of the gas flowing through the gas supply line 34 to the control device 40 and the control device 40 controls the operation of the flow rate regulator 73.

In this embodiment, the control device 40 calculates the temperature of the steam heated by the superheated steam generator 31 on the basis of the pad surface temperature measured by the pad temperature measuring device 10. The control device 40 controls the operation of the superheated steam generator 31 so that the temperature of the superheated steam flowing through the superheated steam supply line 32 matches the calculated steam temperature.

The control device 40 may control the operation of the flow rate regulator 73 on the basis of the pad surface temperature measured by the pad temperature measuring device 10 in addition to or instead of the operation of the superheated steam generator 31. In this case, the control device 40 calculates the temperature of the steam heated by the superheated steam generator 31 and/or the flow rate of the gas flowing through the gas supply line 34. The control device 40 controls the operation of the superheated steam generator 31 and/or the operation of the flow rate regulator 73 so that the temperature of the superheated steam flowing through the superheated steam supply line 32 matches the calculated steam temperature and/or the flow rate of the gas flowing through the gas supply line 34 matches the calculated gas flow rate.

FIG. 21 is a schematic view showing a heating fluid supply system according to still another embodiment. Since a configuration particularly not described in this embodiment is the same as the heating fluid supply system of the embodiment shown in FIG. 2, the duplicated description thereof will be omitted.

The heating fluid supply system shown in FIG. 21 includes a drainage tank 37 to which the exhaust line 36 is connected. A water branch line 38 branching from the water supply line 33 is also connected to the drainage tank 37 and a valve 39 is disposed in the water branch line 38. When the valve 39 is opened, room-temperature water is supplied to the drainage tank 37.

Excess superheated steam flowing through the exhaust line 36 is supplied to the drainage tank 37, is condensed in the drainage tank 37, and is returned to water. In order to efficiently condense the excess superheated steam, room-temperature water is supplied to the drainage tank 37 through the water branch line 38 to decrease the atmospheric temperature inside the drainage tank 37. A drain line 83 is connected to the bottom portion of the drainage tank 37 and the condensed water from the superheated steam is discharged from the polishing apparatus through the drain line 83.

Although not shown in the drawings, the water branch line 38 may be omitted and the drain line 83 may be connected to the superheated steam generator 31. In this case, hot water stored in the drainage tank 37 is supplied to the superheated steam generator 31 and is reused to generate the superheated steam. According to this configuration, it is possible to expect energy-saving operation of the superheated steam generator 31.

FIG. 22 is a schematic view showing a combination of the cooling fluid supply system 50 and the suction mechanism 60 according to another embodiment. The vacuum source 63 of the suction mechanism 60 shown in FIG. 22 is an ejector. A gas branch line 55 branching from the cooling gas supply line 53 of the cooling fluid supply system 52 is connected to the vacuum source 63 and the driving fluid of the vacuum source 63 is a room-temperature gas supplied to the vacuum source 63 through the gas branch line 55. A flow rate regulator 74 (for example, a flow rate adjusting valve) adjusting the flow rate of the driving fluid is disposed in the gas branch line 55. With such a configuration, it is possible to reduce the running cost of the vacuum source 63.

FIG. 23 is a schematic view showing a combination of the heating fluid supply system 30, the cooling fluid supply system 50, and the suction mechanism 60 according to another embodiment. Since an embodiment particularly not described is the same as the embodiment described with reference to FIGS. 21 and 22, the duplicated description thereof will be omitted.

In the cooling fluid supply system 50 shown in FIG. 23, a gas branch line 56 different from the gas branch line 55 supplying a driving fluid to the vacuum source 63 corresponding to an ejector branches from the cooling gas supply line 53. In the following description, the gas branch line 55 is referred to as the first branch line 55 and the gas branch line 56 is referred to as the second branch line 56.

The second branch line 56 is connected to the exhaust line 36. The room-temperature gas flowing to the exhaust line 36 through the second branch line 56 is mixed with the excess superheated steam in the exhaust line 36 to cool the superheated steam. Thus, the cooled superheated steam and the water condensed from the superheated steam are supplied to the drainage tank 37.

The gas discharge line 41 is connected to the drainage tank 37 and the gas discharge line 41 is connected to a discharge line 65 of the vacuum source 63 corresponding to an ejector. The gas flowing from the exhaust line 36 to the drainage tank 37 flows to the discharge line 65 through the gas discharge line 41 and is discharged from the polishing apparatus through the discharge line 65.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A polishing apparatus comprising:
a polishing table which supports a polishing pad;
a polishing head which polishes a substrate by pressing the substrate against a polishing surface of the polishing pad;
a pad temperature measuring device which measures a temperature of the polishing surface;
a pad temperature adjusting device which adjusts the temperature of the polishing surface; and
a control device which controls an operation of the pad temperature adjusting device based on the temperature of the polishing surface measured by the pad temperature measuring device,
wherein the pad temperature adjusting device includes a pad heater which is disposed to be separated upward from the polishing surface, and
wherein the pad heater includes a longitudinal portion which extends in a substantially radial direction of the polishing pad and an injection port which is slit-shaped and formed in a longitudinal direction of the longitudinal portion and injects a heating fluid toward the polishing surface.

2. The polishing apparatus according to claim 1,
wherein the pad temperature adjusting device further includes a vertical movement mechanism which moves the pad heater upward and downward with respect to the polishing surface.

3. The polishing apparatus according to claim 1,
wherein the pad temperature adjusting device further includes a rotating mechanism which rotates the pad heater in a horizontal direction with respect to the polishing surface.

4. The polishing apparatus according to claim 1,
wherein the pad temperature adjusting device further includes a rotation mechanism which rotates the pad heater about a longitudinal axis of the pad heater.

5. The polishing apparatus according to claim 1,
wherein the pad temperature adjusting device further includes a shutter mechanism which adjusts an opening degree of the injection port.

6. The polishing apparatus according to claim 5,
wherein the pad temperature measuring device is a measuring device capable of measuring a temperature profile in a radial direction of the polishing pad, and
wherein the shutter mechanism includes piezo elements arranged in a longitudinal direction of the injection port of the pad heater.

7. The polishing apparatus according to claim 6,
wherein the control device adjusts an expansion and contraction amount of each piezo element based on the temperature profile.

8. The polishing apparatus according to claim 1,
wherein the pad temperature adjusting device further includes a cooling mechanism which injects a cooling fluid to the polishing surface and cools the polishing surface.

9. The polishing apparatus according to claim 8,
wherein the cooling mechanism includes a pad cooler which is disposed to be separated upward from the polishing surface, and
wherein the pad temperature adjusting device further includes a rotation mechanism which rotates the pad cooler about a longitudinal axis of the pad cooler.

10. The polishing apparatus according to claim 8,
wherein the cooling mechanism includes the pad cooler which is disposed to be separated upward from the polishing surface,
wherein the pad cooler includes a longitudinal portion which extends in a substantially radial direction of the polishing pad and a plurality of injection ports which is arranged in a longitudinal direction of the longitudinal portion and injects the cooling fluid toward the polishing surface, and
wherein the cooling mechanism further includes a shutter mechanism which adjusts an opening degree of a plurality of injection ports of the pad cooler.

11. The polishing apparatus according to claim 8,
wherein the cooling mechanism includes the pad cooler which is disposed to be separated upward from the polishing surface, and
wherein the cooling mechanism further includes a guide plate which is attached to the pad cooler and an actuator which rotates the guide plate.

12. The polishing apparatus according to claim 1,
wherein the pad temperature adjusting device further includes a suction mechanism which is disposed above the polishing surface and sucks air above the polishing surface.

13. The polishing apparatus according to claim 1,
wherein the pad temperature adjusting device further includes a heater which is disposed in the pad heater.

14. The polishing apparatus according to claim 1,
wherein the polishing table is disposed in a polishing chamber, and
wherein the pad temperature adjusting device further includes a polishing chamber suction device which sucks air in the polishing chamber so that a pressure in the polishing chamber is maintained at a predetermined value.

15. The polishing apparatus according to claim 1, further comprising:
a cleaning device which cleans the pad heater at a retreat position on a side of the polishing pad.

16. The polishing apparatus according to claim 1,
wherein the heating fluid is superheated steam.

17. The polishing apparatus according to claim 1,
wherein the control device executes a pad temperature adjustment start operation when starting surface temperature control of the polishing pad, and
wherein the pad temperature adjustment start operation is an operation of supplying the heating fluid having a flow rate and/or a temperature larger than a flow rate and/or a temperature of the heating fluid calculated so that the temperature of the polishing surface reaches a target temperature to the pad heater.

18. The polishing apparatus according to claim 17,
wherein the pad temperature adjusting device further includes a heating fluid supply line which supplies the heating fluid to the pad heater and a flow rate regulator which is disposed in the heating fluid supply line, and
wherein the control device increases a flow rate of the heating fluid using the flow rate regulator during the pad temperature adjustment start operation.

19. The polishing apparatus according to claim 17,
wherein the control device ends the pad temperature adjustment start operation when the temperature of the polishing surface of the polishing pad reaches the target temperature.

20. A polishing method of polishing a substrate by pressing the substrate against a polishing surface of a polishing pad while adjusting a temperature of the polishing surface using a pad heater disposed to be separated upward from the polishing surface,
wherein when starting temperature control of the polishing surface, a pad temperature adjustment start operation is executed so that the temperature of the polishing surface reaches a target temperature,
wherein the temperature of the polishing surface is maintained at the target temperature by injecting a heating fluid from an injection port which is slit-shaped and formed in a longitudinal portion of the pad heater based on the temperature of the polishing surface measured by a pad temperature measuring device measuring the temperature of the polishing surface during polishing of the substrate, and
wherein the pad temperature adjustment start operation is an operation of supplying the heating fluid having a flow rate and/or a temperature larger than a flow rate and/or a temperature of the heating fluid calculated so that the temperature of the polishing surface reaches the target temperature to the pad heater.

21. The polishing method according to claim 20,
wherein a step of maintaining the temperature of the polishing surface at the target temperature is executed by at least one of an operation of adjusting the temperature and/or the flow rate of the heating fluid, an operation of adjusting a vertical movement of the pad heater with respect to the polishing surface, an operation of adjusting a rotation operation in a horizontal direction of the pad heater with respect to the polishing surface, and an operation of adjusting a rotation operation of rotating the pad heater about a longitudinal axis of the pad heater.

22. The polishing method according to claim 21,
wherein the flow rate of the heating fluid is adjusted by a shutter capable of adjusting an opening degree of the injection port of the pad heater.

23. The polishing method according to claim 22,
wherein the pad temperature measuring device is a measuring device capable of measuring a temperature profile in a radial direction of the polishing pad,
wherein the shutter includes piezo elements arranged in a longitudinal direction of the injection port of the pad heater, and
wherein the flow rate of the heating fluid is adjusted by adjusting an expansion and contraction amount of each piezo element based on the temperature profile.

24. The polishing method according to claim 20,
wherein a step of maintaining the temperature of the polishing surface at the target temperature is executed by the pad heater and a cooling mechanism for cooling the polishing surface by injecting a cooling fluid to the polishing surface.

25. The polishing method according to claim 24,
wherein the cooling mechanism includes a pad cooler which is disposed to be separated upward from the polishing surface,
wherein the pad cooler includes a longitudinal portion which extends in a substantially radial direction of the polishing pad and a plurality of injection ports which is arranged in a longitudinal direction of the longitudinal portion and injects the cooling fluid toward the polishing surface, and
wherein a step of maintaining the temperature of the polishing surface at the target temperature is executed by further adding at least one of an operation of adjusting a rotation operation of rotating the pad cooler about a longitudinal axis of the pad cooler, an operation of adjusting an opening degree of the plurality of injection ports of the pad cooler by a shutter, and an operation of adjusting a rotation operation of a guide plate attached to the pad cooler.

26. The polishing method according to claim 20,
wherein the pad temperature adjustment start operation is an operation of increasing the flow rate of the heating fluid using a flow rate regulator disposed in a heating fluid supply line supplying the heating fluid to the pad heater.

27. The polishing method according to claim 20,
wherein when the temperature of the polishing surface of the polishing pad reaches the target temperature, the pad temperature adjustment start operation is ended.
